(19) United States
(12) Patent Application Publication
(10) Pub. No.: US 2024/0196537 A1
(43) Pub. Date: Jun. 13, 2024

(54) SEMICONDUCTOR PACKAGE ASSEMBLY

(71) Applicant: MEDIATEK INC., Hsinchu City (TW)

(72) Inventors: Hui-Chi TANG, Hsinchu City (TW); Pei-San CHEN, Hsinchu City (TW); Shao-Chun HO, Hsinchu City (TW); Bo-Jiun YANG, Hsinchu City (TW)

(21) Appl. No.: 18/510,815

(22) Filed: Nov. 16, 2023

Related U.S. Application Data
(60) Provisional application No. 63/386,513, filed on Dec. 8, 2022.

(51) Int. Cl. H05K 1/18; H01L 25/16; H05K 1/02

(52) U.S. Cl. CPC H05K 1/181; H01L 25/16; H05K 1/0296; H01L 24/16; H01L 2224/16227

(57) ABSTRACT

A semiconductor package assembly is provided. The semiconductor package assembly includes a base, a semiconductor package, and a capacitor. The base has a top surface and a bottom surface. The semiconductor package is disposed on the top surface of the base. The capacitor is disposed on the semiconductor package and located between the semiconductor package and the base. The capacitor has a back surface located away from the semiconductor package. The back surface of the capacitor is higher than the bottom surface of the base and lower than the top surface of the base.

### CROSS REFERENCE TO RELATED APPLICATIONS

This application claims the benefit of U.S. Provisional Application No. 63/386,513, filed on Dec. 8, 2022, the entirety of which is incorporated by reference herein.

### BACKGROUND OF THE DISCLOSURE

### Field of the Disclosure

The present disclosure relates to a semiconductor package assembly and, in particular, to a semiconductor package assembly that includes a capacitor.

### Description of the Related Art

In order to ensure the continued miniaturization and multi-functionality of electric products and communication devices, it is desired that semiconductor packages be small in size, support multi-pin connection, operate at high speeds, and have high functionality. This will put pressure on semiconductor package fabricators to develop fan-out semiconductor packages. However, the increased number of input/output connections in a multi-functional chip package may lead to thermal electrical problems, such as heat dissipation, cross talk, signal propagation delay, and electromagnetic interference in RF circuits. These thermal electrical problems may affect the reliability and quality of the finished product.

Thus, a novel semiconductor package assembly is desirable.

### BRIEF SUMMARY OF THE DISCLOSURE

An embodiment of the present disclosure provides a semiconductor package assembly. The semiconductor package assembly includes a base, a semiconductor package, and a capacitor. The base has a top surface and a bottom surface. The semiconductor package is disposed on the top surface of the base. The capacitor is disposed on the semiconductor package and located between the semiconductor package and the base. The capacitor has a back surface located away from the semiconductor package. The back surface of the capacitor is higher than the bottom surface of the base and lower than the top surface of the base.

In some embodiments, the semiconductor package assembly further includes first contact pads, second contact pads and conductive structures. The first contact pads and second contact pads are disposed on the semiconductor package and close to the base. The conductive structures are disposed on the first contact pads and electrically connected between the semiconductor package and the base, wherein the capacitor is disposed on the second contact pads and surrounded by the conductive structures. In some embodiments, a first height of the capacitor is greater than a second height of the conductive structures. In some embodiments, the base includes a build-up layer structure, a first conductive layer and a first solder mask layer. The build-up layer structure has a top surface close to the semiconductor package. The first conductive layer is disposed on the top surface of the build-up layer structure. The first solder mask layer is disposed on the first conductive layer. The top surface of the base is a top surface of the first solder mask layer, and wherein the first solder mask layer has a first opening for accommodate at least a portion of the capacitor. In some embodiments, the first solder mask layer has a second opening aligned to the first opening. The at least a portion of the capacitor further extends to the second opening. In some embodiments, the first opening and the second opening surround side surfaces of the capacitor, and wherein the side surfaces are connected to the back surface of the capacitor. In some embodiments, the back surface of the capacitor is higher than the top surface of the build-up layer structure and lower than the top surface of the first solder mask layer. In some embodiments, the back surface of the capacitor is higher than a top surface of the first conductive layer and lower than the top surface of the first solder mask layer. In some embodiments, the base includes a second conductive layer and a solder paste pattern. The second conductive layer is disposed on the top surface of the build-up layer structure, and in the second opening of the first conductive layer. The solder paste pattern is disposed on the second conductive layer and in contact with the capacitor and the second conductive layer. In some embodiments, the second conductive layer is separate from the first conductive layer. In some embodiments, the second conductive layer is electrically connected to the ground plane of the base. In some embodiments, an area occupied by the solder paste pattern is between 40% and 60% of an area of the second conductive layer. In some embodiments, the solder paste pattern comprises a pattern of a hollow square, a hollow circle, a square, a rectangle, a circle, a criss-cross sign, the letter X, an equals sign, parallel lines, or a combination thereof. In some embodiments, a first thickness of the first solder mask layer is greater than a second thickness of the solder paste pattern. In some embodiments, the thickness of the second conductive layer is less than the thickness of the first conductive layer.

An embodiment of the present disclosure provides a semiconductor package assembly. The semiconductor package assembly includes a base, a semiconductor package and a capacitor. The base has a top surface. The semiconductor package is disposed on the top surface of the base by conductive structures. The conductive structures are connected between the top surface of the base and the semiconductor package. The capacitor is disposed on the semiconductor package and surrounded by the conductive structures. The capacitor partially overlaps the base in a direction substantially parallel with the top surface of the base.

In some embodiments, the base includes a build-up layer structure, a first conductive layer and a first solder mask layer. The build-up layer structure has a top surface close to the semiconductor package. The first conductive layer is disposed on the top surface of the build-up layer structure. The first solder mask layer is disposed on the first conductive layer. The first solder mask layer has a first opening. The capacitor partially overlaps the first solder mask layer of the base in the direction substantially parallel with the top surface of the base. The first conductive layer has a second opening aligned to the first opening. The capacitor partially overlaps the first solder mask layer and the first conductive layer of the base in the direction. In some embodiments, the base includes a second conductive layer and a solder paste pattern. The second conductive layer is disposed on the top surface of the build-up layer structure and in the second opening of the first conductive layer. The solder paste pattern is disposed on a portion the second conductive layer and directly connected between the capacitor and the second conductive layer. In some embodiments, an area occupied by the solder paste pattern is between 40% and 60% of an area of the second conductive layer.

### BRIEF DESCRIPTION OF THE DRAWINGS

The present disclosure can be more fully understood by reading the subsequent detailed description and examples with references made to the accompanying drawings, wherein:

FIG. 1A is a schematic cross-sectional view of a semiconductor package assembly in accordance with some embodiments of the disclosure;

FIG. 1B is a schematic cross-sectional view of a semiconductor package assembly in accordance with some embodiments of the disclosure;

FIG. 2 is a schematic cross-sectional view of a semiconductor package assembly in accordance with some embodiments of the disclosure; and

FIGS. 3A, 3B, 3C, 3D, 3E, 3F, 3G, 3H and 3I are schematic top views of a region of a base of the semiconductor package assembly of FIG. 2 in accordance with some embodiments of the disclosure, showing designs of solder paste patterns on a conductive layer of the base.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

As high performance integrated circuit packaging demands larger currents at higher frequencies with lower power-supply voltages, power system design becomes increasingly challenging. In order to ensure the continued miniaturization and multi-functionality of electric products and communication devices, capacitors may be adopted to act as temporary charge reservoirs to prevent momentary fluctuations in supply voltage and enable the system to maintain a near-constant voltage across all operating frequencies. For example, when a supply voltage is provided to supply the power needed for electronic circuits to operate. During operation, the supply voltage may supply transient currents with a relatively high intensity, which results in improper operation of the electronic circuits. In order to provide a more stable power supply, decoupling capacitors are connected between the supply voltage and ground to provide a bypass path for transient currents. That is, the decoupling capacitors function as temporary charge reservoirs.

In addition, the decoupling capacitors can reduce the impact of electromagnetic interference (EMI) issues and improve signal performance by stabilizing current flow. As semiconductor package structures are gradually miniaturized, the problem of EMI increases dramatically, so does the importance of decoupling capacitors. Furthermore, decoupling capacitors mounted on the land-side of the package substrate can improve the signal and power integrity (SI/PI) of the semiconductor package.

However, although existing semiconductor packages are generally adequate, they have not been satisfactory in every respect. For example, bump structures are removed for land-side capacitors (LSCs). This reduces current density and heat dissipation paths. Heat is generated during operation of the semiconductor die. If the heat is not adequately removed, the increased temperature may result in damage to the semiconductor components. In addition, the package height shrinkage is limited by the height (in z-direction) of the land-side capacitors mounted on the semiconductor package. Therefore, further improvements to the semiconductor package structures are required.

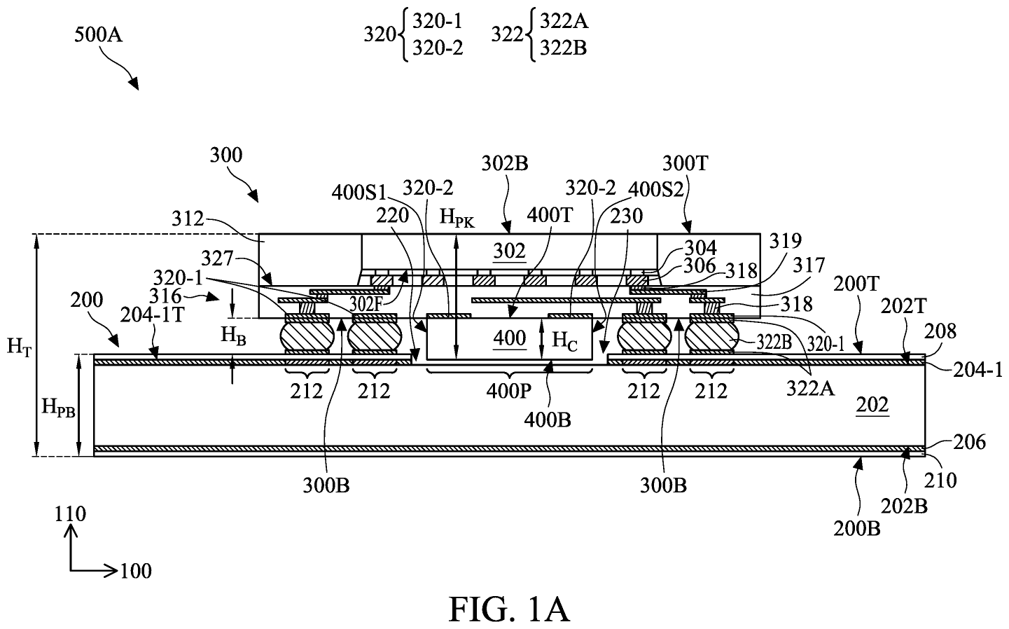

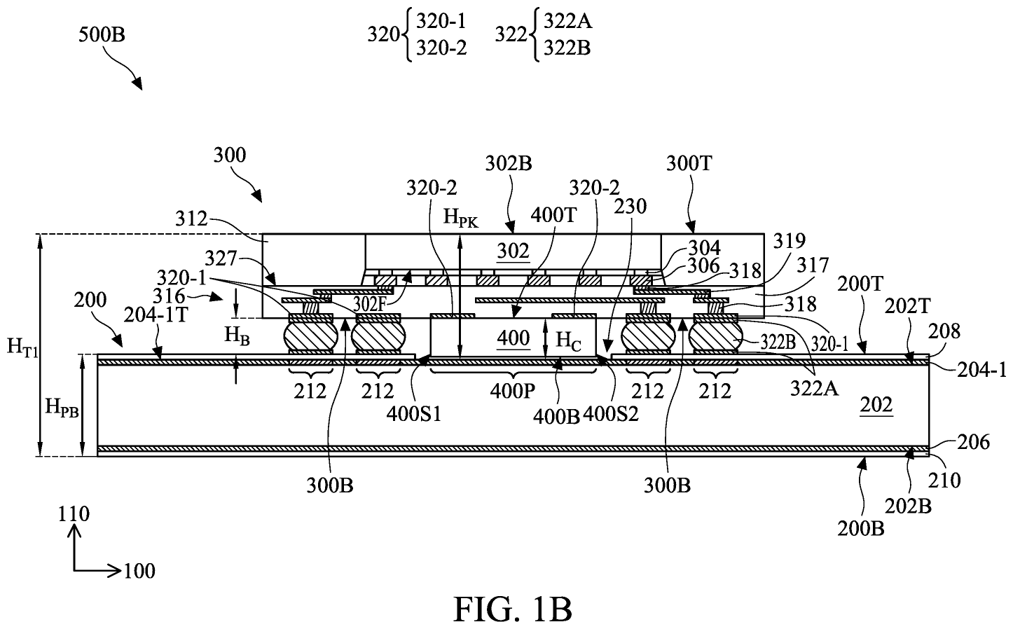

FIG. 1A is a schematic cross-sectional of a semiconductor package assembly 500A in accordance with some embodiments of the disclosure. In some embodiments, the semiconductor package assembly 500A can be used to form a fan-out package, a two-dimensional (2D) package, a 2.5D package, a three-dimensional (3D) semiconductor package, or another suitable package. The semiconductor package assembly 500A may include one wafer-level fan-out semiconductor package or more than one vertically stacked wafer-level fan-out semiconductor packages mounted on a base 200. As shown in FIG. 1A, in some embodiments, the semiconductor package assembly 500A includes a semiconductor package 300 and a capacitor 400.

As shown in FIG. 1A, the base 200, for example a printed circuit board (PCB), may include a build-up layer structure 202, a topmost conductive layer 204-1, a bottommost conductive layer 206 and solder mask layers 208, 210. In some embodiments, the thickness of the solder mask layer 208 may be between 15 um and 25 um. In some embodiments, the thickness of the topmost conductive layer 204-1 may be between 20 um and 40 um. In some embodiments, the build-up layer structure 202 may have a top surface 202T and a bottom surface 202B. The top surface 202T of the build-up layer structure 202 is close to the semiconductor package 300 and the capacitor 400, while the bottom surface 202B of the build-up layer structure 202 is away from the semiconductor package 300 and the capacitor 400. In some embodiments, the topmost conductive layer 204-1 formed on the top surface 202T of the build-up layer structure 202, and the bottommost conductive layer 206 formed on the bottom surface 202B of the build-up layer structure 202. In some embodiments, the solder mask layer 208 formed on the topmost conductive layer 204-1, and the solder mask layer 210 formed on the bottommost conductive layer 206. In some embodiments, the build-up layer structure 202 may include a core substrate (not shown) and a plurality of alternating laminated conductive layers (not shown) and dielectric layers (not shown) stacked on opposite sides of the core substrate. In some embodiments, the build-up layer structure 202 may by fabricated without the core substrate and the build-up layer structure 202 may include a plurality of alternating laminated conductive layers (not shown) and dielectric layers (not shown). The top surface 202T is located close to the semiconductor package 300, and the bottom surface 202B is located away from the semiconductor package 300. It is noted that the topmost layer and the bottommost layer of the build-up layer structure 202 are dielectric layers (not shown) in this embodiment. Therefore, the topmost dielectric layer and the bottommost dielectric layers may be exposed from the top surface 202T and the bottom surface 202B of the build-up layer structure 202. In some embodiments, the core substrate may be formed of polypropylene (PP), Pre-preg, FR-4 and/or other epoxy laminate material. In some embodiments, the conductive layer includes a conductive material, such as metals comprising copper, gold, silver, or other applicable metals. In some embodiments, the dielectric layer includes Pre-preg or other applicable dielectric materials.

The topmost conductive layer 204-1 may be formed on the top surface 202T of the build-up layer structure 202. As shown in FIG. 1A, the topmost conductive layer 204-1 may have an opening 230 passing through it. In some embodiments, the topmost conductive layer 204-1 may include a single layer or a multilayer structure. In addition, the topmost conductive layer 204-1 may include conductive traces (not shown), pads 212 and ground planes (not shown) disposed on the base 200. In some embodiments, the conductive traces may comprise signal trace segments or ground trace segments, which are used for the input/output (I/O) connections of the semiconductor package 300. In some embodiments, the pads 212 are connected to different terminals of the conductive traces. The pads 212 are used for the semiconductor package 300 that is mounted directly on them. In some embodiments, the ground planes are grounded and connected to ground pads of the semiconductor package 300. In some embodiments, the topmost conductive layer 204-1 includes a conductive material, such as metals comprising copper, gold, silver, or other applicable metals. For example, the topmost conductive layer 204-1 may be a copper layer 204-1.

The bottommost conductive layer 206 may be formed on the bottom surface 202B of the build-up layer structure 202. In some embodiments, the topmost and bottommost conductive layers 204-1, 206 may include the same or similar materials and structures. For example, the bottommost conductive layer 206 may be a copper layer 206.

The solder mask layer 208 may be disposed on the top surface 202T of the build-up layer structure 202 and the solder mask layer 208 may be directly disposed on the topmost conductive layer 204-1. The solder mask layer 208 may have an opening 230 aligned to the opening 220 of the topmost conductive layer 204-1, so that a portion of the top surface 202T (and a portion of the topmost dielectric layer) of the build-up layer structure 202 is exposed from the opening 220 of the topmost conductive layer 204-1 and the opening 230 of the solder mask layer 208. The solder mask layer 208 may have other openings (not shown) to expose pads 212. In some embodiments, the solder mask layer 208 may include an epoxy resin. In some embodiments, a top surface 200T of the solder mask layer 208 close to the semiconductor package 300 may serve as the top surface 200T (which also serves as a chip-attach surface) of the base 200.

The solder mask layer 210 may be disposed on the bottom surface 202B of the build-up layer structure 202 and on the bottommost conductive layer 206. In some embodiments, the solder mask layers 208 and 210 may include the same or similar materials. The solder mask layer 208 may have openings (not shown) to expose pads (not shown) connected to conductive traces (not shown) of the bottommost conductive layer 206. Unlike the solder mask layer 208, the solder mask layer 210 and the bottommost conductive layer 206 might not have aligned openings to expose the bottom surface 202B (and the bottommost dielectric layer) of the build-up layer structure 202. In some embodiments, a bottom surface 200B of the solder mask layer 210 located away from the semiconductor package 300 may serve as a bottom surface 200B of the base 200.

The semiconductor package 300 is disposed on the top surface 202T of the base 200. The semiconductor package 300 is mounted on the top surface 200T of the base 200 using conductive structures 322 by a surface mount technology (SMT) process. In some embodiments, the semiconductor package 300 may include a fan-out package such as a system-on-chip (SOC) package, a memory package or a hybrid package (for packaging logic and memory dies). The semiconductor package 300 may include at least one semiconductor die 302 and a substrate 316. For example, the semiconductor die 302 may include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (IO) die, a dynamic random access memory (DRAM) IP core, a static random-access memory (SRAM), a high bandwidth memory (HBM), a dynamic random access memory (DRAM) controller, a dynamic random access memory or any combination thereof.

As shown in FIG. 1A, the semiconductor die 302 is disposed on a surface 327 (which also serves as a die-side surface 327) of the substrate 316 located away from the conductive structures 322. The semiconductor die 302 has a back surface 302B and a front surface 302F. The semiconductor die 302 may be fabricated by a flip-chip technology. The back surface 302B of the semiconductor die 302 may be aligned with or lower than a top surface 300T of the semiconductor package 300. Pads 304 of the semiconductor die 302 are disposed on the front surface 302F to be electrically connected to the circuitry (not shown) of the semiconductor die 302. In some embodiments, the pads 304 belong to the uppermost metal layer of the interconnection structure (not shown) of the semiconductor die 302. The pads 304 of the semiconductor die 302 are electrically connected to the substrate 316 using conductive structures 306. In some embodiments, the conductive structures 306 include conductive materials, such as metal. The conductive structures 306 may include microbumps, controlled collapse chip connection (C4) bumps, ball grid array (BGA) balls, the like, or a combination thereof. In some embodiments, an underfill (not shown) is introduced into the gap between the semiconductor die 302 and the substrate 316.

As shown in FIG. 1A, the substrate 316 is provided for the semiconductor die 302 to be disposed upon. The substrate 316 is electrically connected to the semiconductor die 302 by the pads 304 of the semiconductor die 302. In some embodiments, the substrate 316 includes a redistribution layer (RDL) structure having one or more conductive traces 319, one or more vias 318 disposed in one or more intermetal dielectric (IMD) layers 317 and contact pads 320. The conductive traces 319 are electrically connected to the corresponding contact pads 320. The contact pads 320 including contact pads 320-1 and 320-2 are exposed to openings of the solder mask layer (not shown) and close to the base 200. In addition, the conductive structures 322 are disposed on a surface 300B (which also serves as a land-side surface 300B) of the substrate 316 located away from the semiconductor die 302. The conductive structures 322 are disposed on and in contact with the corresponding the contact pads 320-1. Therefore, the conductive structures 322 are electrically connected between the contact pads 320-1 of the semiconductor package 300 and the pads 212 of the base 200. The surface 300B of the substrate 316 may also serve as the bottom surface 300B of the semiconductor package 300. In some embodiments, the vias 318, the conductive traces 319 and the contact pads 320 include a conductive material, such as metals comprising copper, gold, silver, or other applicable metals. The dielectric layers 317 may include extra-low K (ELK) dielectrics and/or ultra-low K (ULK) dielectric. In addition, the dielectric layers 317 may include epoxy. However, it should be noted that the number of dielectric layers 317, that the number of vias 318, the number of conductive traces 319 and the number of contact pads 320 shown in FIG. 1A are only an example and are not a limitation to the present disclosure.

As shown in FIG. 1A, the semiconductor package 300 further includes a molding compound 312 disposed on the surface 327 of the substrate 316 and the molding compound 312 surrounds the semiconductor die 302. The molding compound 312 is in contact with the substrate 316 and the semiconductor die 302. The back surface 302B of the semiconductor die 302 is exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the semiconductor die 302, and then may be cured using a UV or thermally curing process. The molding compound 312 may be cured with a mold.

As shown in FIG. 1A, the conductive structures 322 are disposed between the semiconductor package 300 and the base 200. The conductive structures 322 are disposed on the surface 300B (which is located away from the semiconductor die 302) of the substrate 316, and the conductive structures 322 are in contact with the contact pads 320-1 of the substrate 316 and the corresponding pads 212 of the base 200. Therefore, the semiconductor package 300 is electrically connected to the base 200 via the conductive structures 222. In some embodiments, the conductive structures 322 comprise an under bump metallurgy (UBM) structure 322A and a conductive ball structure 322B on the UBM structure 322A. The conductive ball structure may include a copper ball, a conductive bump structure such as a copper bump or a solder bump structure, or a conductive pillar structure such as a copper pillar structure. For example, the conductive structures 322 may be controlled collapse chip connection (C4) structures composed of conductive pillar structures and conductive bump structures.

As shown in FIG. 1A, the capacitor 400, such as a land-side capacitor (LSC), is disposed on the semiconductor package 300 and the capacitor 400 is located between the semiconductor package 300 and the base 200. The capacitor 400 may be mounted on the surface 300B of the substrate 316 (which also serves as the bottom surface 300B of the semiconductor package 300) opposite the semiconductor die 302. In some embodiments, the capacitor 400 is disposed on and electrically connected to the contact pad 320-2 of the semiconductor package 300. In addition, the capacitor 400 is surrounded by or arranged between the conductive structures 322. Furthermore, the capacitor 400 does not have to be covered by a molding compound.

The capacitor 400 has a front surface 400T, a back surface 400B and side surfaces 400S1, 400S2. The side surfaces 400S1, 400S2 are connected between the front surface 400T and the back surface 400B. The front surface 400T of the capacitor 400 is located close to the semiconductor package 300. The capacitor 400 may have pads (not shown) on the front surface 400T and the capacitor 400 is electrically connected to the contact pad 320-2 of the semiconductor package 300. The back surface 400B of the capacitor 400 is located away from the semiconductor package 300 and close to the base 200.

In some embodiments, the opening 220 of the topmost conductive layer 204-1 and the opening 230 of the solder mask layer 208 aligned to each other, which provides an additional space for accommodate at least a portion of the capacitor 400. As a result, a total height Hr of the semiconductor package assembly 500A along a direction 110 (which also serves as z-direction) is reduced. More specifically, the total height Hr of the semiconductor package assembly 500A may be lower than a total of a height HPB of the base 200 and a height HPK of the semiconductor package 300. The total height Hr of the semiconductor package assembly 500A is measured from the top surface 300T of the semiconductor package 300 to the bottom surface 200B of the base 200. The height HPB of the base 200 is measured from the top surface 200T of the base 200 to the bottom surface 200B of the base 200. The height HPK of the semiconductor package 300 is measured from the top surface 300T of the semiconductor package 300 to the bottom surface 400B of the capacitor 400. In some embodiments, a portion of the capacitor 400 may extends into the opening 230 of the solder mask layer 208 to reduce the total height HT. In some embodiments, a portion of the capacitor 400 extends into the opening 230 of the solder mask layer 208 and extends to the opening 220 of the topmost conductive layer 204-1 to further reduce the total height HT. As shown in FIG. 1A, in some embodiments, a portion of the capacitor 400 may extends into both the opening 220 of the topmost conductive layer 204-1 and the opening 230 of the solder mask layer 208 to further reduce the total height HT. The opening 220 of the topmost conductive layer 204-1 and the opening 230 of the solder mask layer 208 surround portions of the side surfaces 400S1, 400S2 of the capacitor 400. In some embodiments, the back surface 400B of the capacitor 400 may be higher than the bottom surface 200B of the base 200, and the back surface 400B of the capacitor 400 may be lower than the top surface 200T (which also serves as the top surface 200T of the base 200) of the solder mask layer 208. More specifically, the back surface 400B of the capacitor 400 may be higher than the top surface 202T of the build-up layer structure 202, and the back surface 400B of the capacitor 400 may be lower than the top surface 200T (which also serves as the top surface 200T of the base 200) of the solder mask layer 208. In some embodiments, the back surface 400B of the capacitor 400 may be higher than the bottom surface 200B of the base 200, and the back surface 400B of the capacitor 400 may be lower than a top surface 204-1T of the topmost conductive layer 204-1. More specifically, the back surface 400B of the capacitor 400 may be higher than the top surface 202T of the build-up layer structure 202, and the back surface 400B of the capacitor 400 may be lower than the top surface 204-1T of the topmost conductive layer 204-1. In some embodiments, the back surface 400B of the capacitor 400 may be higher than the top surface 204-1T of the topmost conductive layer 204-1, and the back surface 400B of the capacitor 400 may be lower than the top surface 200T (which also serves as the top surface 200T of the base 200) of the solder mask layer 208. As a result, all the above embodiments can reduce the total height HT of the semiconductor package assembly 500A, and the desired design can be selected according to different requirements. Therefore, the embodiments of the present disclosure provide design elasticity and flexibility.

In some embodiments, the capacitor 400 may partially overlap the base 200 in a direction 100 (the lateral direction or the xy-direction) that is substantially parallel with the top surface 200T of the base 200. Since the capacitor 400 partially overlaps the base 200 along the direction 100, a height H_{C} of the capacitor 400 may be greater than a height H_{B} of the conductive structures 322. In some embodiments, the height H_{B} of the conductive structures 322 may be less than 150 um, such as greater than 100 um and less than 150 um. In some embodiments, the capacitor 400 may partially overlap the topmost conductive layer 204-1 and the solder mask layer 208 in the direction 100 that is substantially parallel with the top surface 200T of the base 200. In some embodiments, the capacitor 400 may partially overlap the solder mask layer 208 in the direction 100 that is substantially parallel with the top surface 200T of the base 200, and the capacitor 400 does not overlap the topmost conductive layer 204-1 in the direction 100.

In some embodiments as shown in FIG. 1A, the capacitor 400 is separate from the base 200. The side surfaces 400S1, 400S2 and the back surface 400B of the capacitor 400 are not in contact with the base 200 and exposed to air. In other words, there is a gap between the back surface 400B of the capacitor 400 and the top surface 202T of the build-up layer structure 202. A vertical projection 400P of the capacitor 400 on the top surface 202T of the build-up layer structure 202 is located within the opening 220 of the topmost conductive layer 204-1 and the opening 230 of the solder mask layer 208. In some embodiments, the capacitor 400 includes a multilayer ceramic capacitor (MLCC), a silicon capacitor or another applicable capacitor.

In some embodiments as shown in FIG. 1A, the base 200 of the semiconductor package assembly 500A may provide an additional space formed by the aligned openings of the topmost conductive layer 204-1 and the overlying solder mask layer 208. At least a portion of the land-side capacitor (the capacitor 400) can be accommodated in the additional space. Therefore, the height H_{B} of the conductive structures 322 may be reduced, and the total height Hr of the semiconductor package assembly 500A may be also reduced.

FIG. 1B is a schematic cross-sectional of a semiconductor package assembly 500B in accordance with some embodiments of the disclosure. Elements of the embodiments hereinafter, that are the same or similar as those previously described with reference to FIG. 1A, are not repeated for brevity. As shown in FIG. 1B, the difference between the semiconductor package assembly 500A and the semiconductor package assembly 500B at least includes that the topmost conductive layer 204-1 of the semiconductor package assembly 500B does not include the opening 220 (as shown in FIG. 1A) corresponding to the capacitor 400. In some embodiments, the opening 230 of the solder mask layer 208 is provided an additional space for accommodate at least a portion of the capacitor 400. As a result, the total height H_{T1} of the semiconductor package assembly 500B along a direction 110 (which also serves as z-direction) is reduced. More specifically, the total height H_{T1} of the semiconductor package assembly 500B may be lower than the total of the height HPB of the base 200 and the height HPK of the semiconductor package 300. As shown in FIG. 1B, a portion of the capacitor 400 may extends into the opening 230 of the solder mask layer 208. The opening 230 of the solder mask layer 208 surrounds portions of the side surfaces 400S1, 400S2 of the capacitor 400. In some embodiments, the back surface 400B of the capacitor 400 is higher than the top surface 204-1T of the topmost conductive layer 204-1, and the back surface 400B of the capacitor 400 is lower than the top surface 200T (which also serves as the top surface 200T of the base 200) of the solder mask layer 208. In some embodiments, the capacitor 400 is separate from the base 200. In some embodiments, there is a gap (not show) between the back surface 400B of the capacitor 400 and the top surface 204-1T of the topmost conductive layer 204-1. In some embodiments, the capacitor 400 partially overlap the solder mask 208 in the direction 100 that is substantially parallel with the top surface 200T of the base 200, and the capacitor 400 does not overlap the topmost conductive layer 204-1 in the direction 100. This embodiment provides an alternative design approach, thereby increasing the design flexibility of the disclosure.

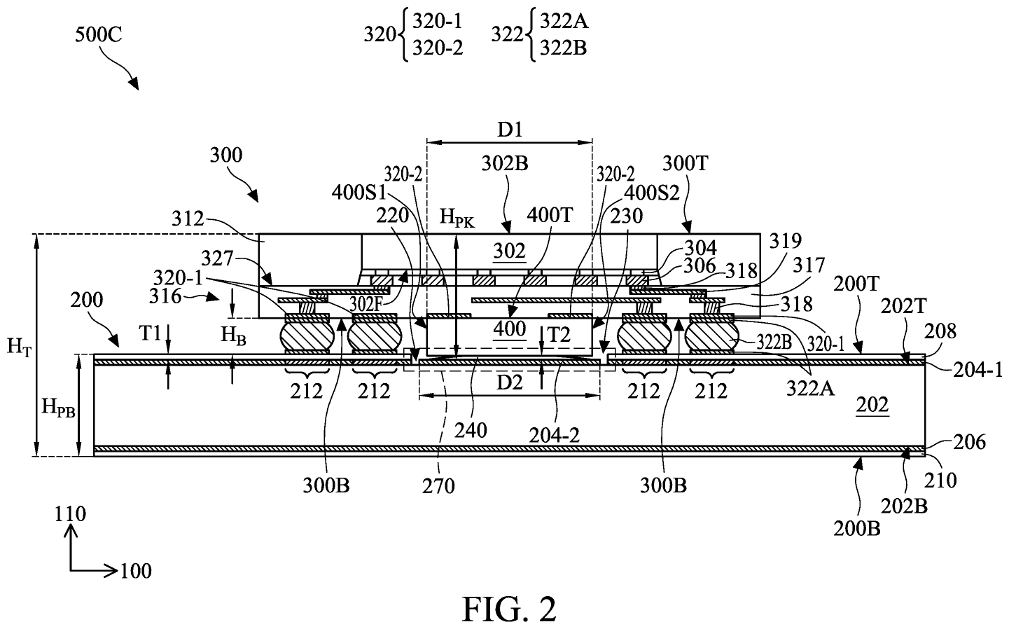

In some embodiments, the capacitor (land-side capacitor) 400 may be connected to an individual conductive layer of the base 200 by a solder paste in order to improve the thermal performance of the semiconductor package assembly 500. FIG. 2 is a schematic cross-sectional of a semiconductor package assembly 500C in accordance with some embodiments of the disclosure. Elements of the embodiments hereinafter, that are the same or similar as those previously described with reference to FIG. 1A, are not repeated for brevity. As shown in FIG. 2, the difference between the semiconductor package assembly 500A and the semiconductor package assembly 500C at least includes that the base 200 of the semiconductor package assembly 500C further includes a conductive layer 204-2 and a solder paste pattern 240 corresponding to the capacitor 400.

As shown in FIG. 2, the conductive layer 204-2 is disposed on the top surface 202T of the build-up layer structure 202 (or the topmost dielectric of the build-up layer structure 202) and the conductive layer 204-2 is disposed in the opening 220 of the topmost conductive layer 204-1. The conductive layer 204-2 may be located close to the top surface 200T of the base 200 and directly under the capacitor 400. In some embodiments, a dimension D1 of the capacitor 400 is less than or equal to a dimension D2 of the conductive layer 204-2 along the direction 100. In addition, the conductive layer 204-2 may be located beside and separate from the topmost conductive layer 204-1. In some embodiments, the conductive layer 204-2 is electrically connected to the ground plane (not shown) of the base 200. In some embodiments, the thickness of the conductive layer 204-2 may be between 20 um and 40 um. In some embodiments, the thickness (not shown) of the conductive layer 204-2 may be less than the thickness (not shown) of the topmost conductive layer 204-1 along the direction 110 to ensure the installation stability of capacitor 400 and the semiconductor package 300. In some embodiments, the topmost conductive layer 204-1 and the conductive layer 204-2 may have the same or similar material and formed simultaneously or separately using the deposition process and the subsequent patterning process.

The solder paste pattern 240 may be disposed on the conductive layer 204-2 and directly connected between the capacitor 400 and the conductive layer 204-2. In other words, the solder paste pattern 240 may be disposed on the conductive layer 204-2 and in contact with the capacitor 400 and the conductive layer 204-2. In some embodiments, the solder paste pattern 240 is separate from the topmost conductive layer 204-1 and the solder mask layer 208. In some embodiments, a thickness T1 of the solder mask layer 208 is greater than a thickness T2 of the solder paste pattern 240, thereby keeping the total height Hr of the semiconductor package assembly 500C as smaller as possible while the capacitor 400 is connected to the conductive layer 204-2 by the solder paste pattern 240. As a total of the thickness of the conductive layer 204-2 and the thickness T2 of the solder paste pattern 240 is less than a total of the thickness of the topmost conductive layer 204-1 and the thickness T1 of the solder mask layer 208, the total height HT of the semiconductor package assembly 500C is reduced. More specifically, the total height HT may be lower than a total of the height HPB of the base 200 and the height HPK of the semiconductor package 300. Moreover, the heat of the semiconductor package 300 and the capacitor 400 can be transferred (for example, transferred to the ground plane) through the solder paste pattern 240 and the conductive layer 204-2, thereby improving the heat dissipation efficiency of the semiconductor package assembly 500C.

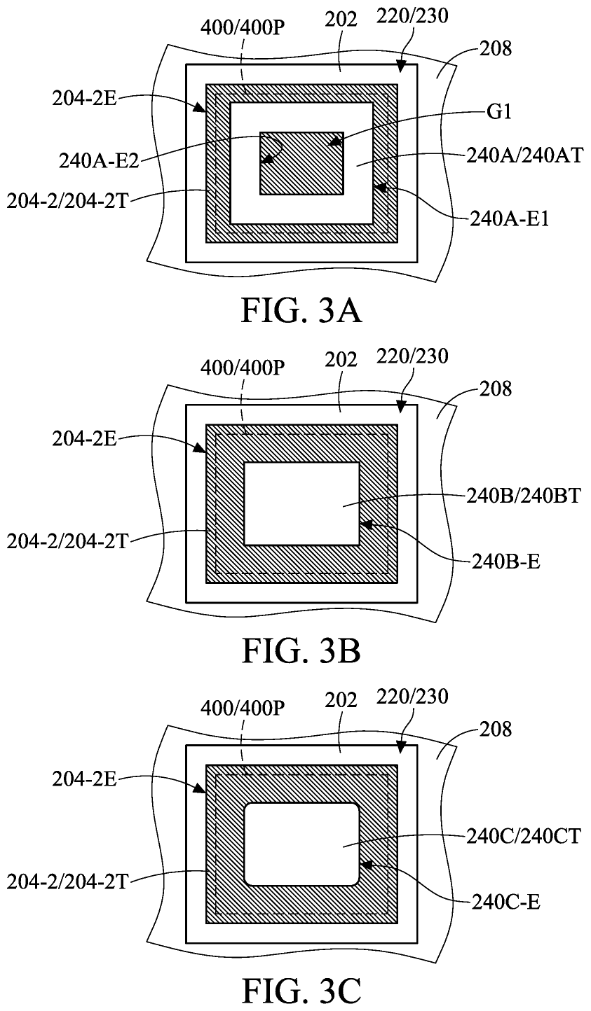

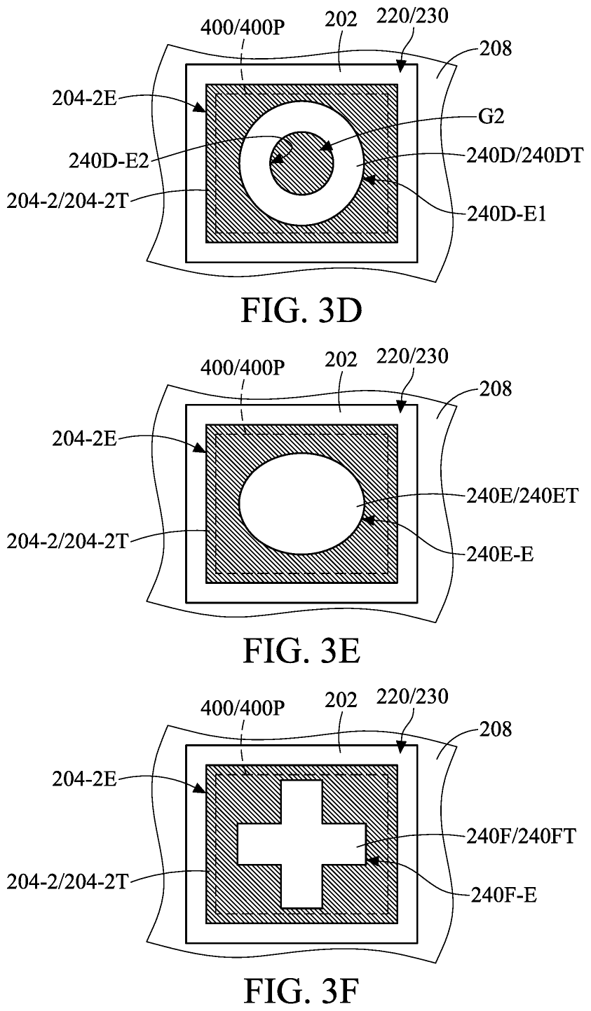

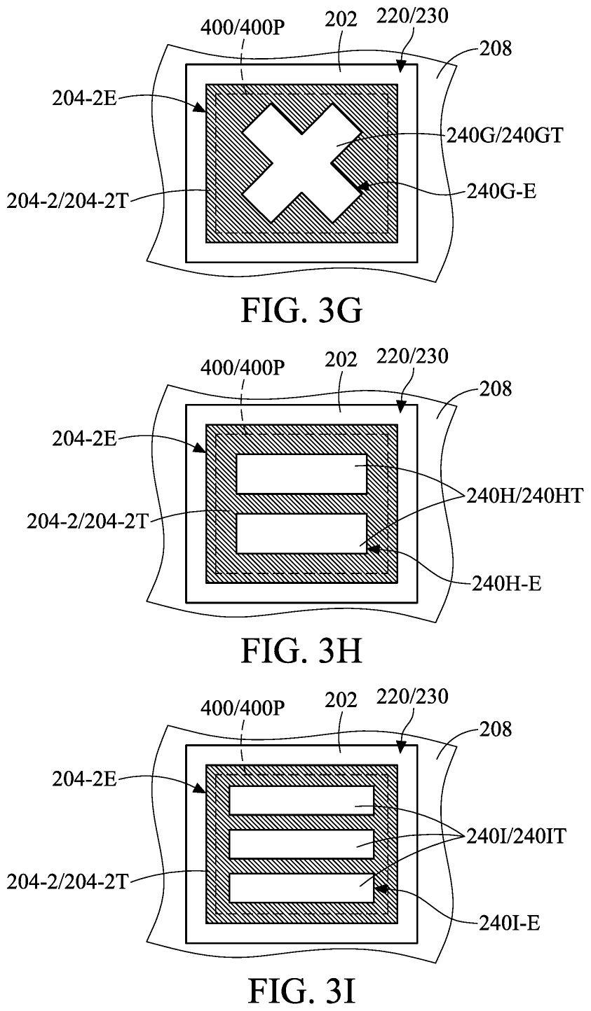

FIGS. 3A, 3B, 3C, 3D, 3E, 3F, 3G, 3H and 3I are schematic top views of a region 270 of the base 200 of the semiconductor package assembly 500C of FIG. 2 in accordance with some embodiments of the disclosure, showing designs of solder paste patterns 240 on the conductive layer 204-2 of the base 200. In some embodiments, the solder paste pattern 240 (including solder paste patterns 240A, 240B, 240C, 240D, 240E, 240F, 240G, 240G, 240H and 240I) disposed on a portion the conductive layer 204-2. In other words, the solder paste pattern 240 may partially cover the conductive layer 204-2. In in the top views as shown in FIGS. 3A to 3I, the solder paste patterns 240A, 240B, 240C, 240D, 240E, 240F, 240G, 240H and 240I may have top view areas 240AT, 240BT, 240CT, 240DT, 240ET, 240FT, 240GT, 240HT and 240IT. In addition, the conductive layer 204-2 may have a top view area 204-2T. In some embodiments, each of the top view areas 240AT, 240BT, 240CT, 240DT, 240ET, 240FT, 240GT, 240HT and 240IT may be between 40% and 60% of the top view area 204-2T. In other words, each of the areas 240AT, 240BT, 240CT, 240DT, 240ET, 240FT, 240GT, 240HT and 240IT occupied by the solder paste pattern may be between 40% and 60% of the area of the conductive layer 204-2. If the top view areas 240AT, 240BT, 240CT, 240DT, 240ET, 240FT, 240GT, 240HT and 240IT are lower than 40% of the top view area 204-2T, the volume of the solder paste patterns 240A, 240B, 240C, 240D, 240E, 240F, 240G, 240H and 240I may be not large enough to achieve the goals of dissipating the heat generated from the capacitor 400 to the conductive layer 204-2 quickly and attaching the capacitor 400 to the conductive layer 204-2 stably. If the top view areas 240AT, 240BT, 240CT, 240DT, 240ET, 240FT, 240GT, 240HT and 240IT are greater than 60% of the top view area 204-2T, the volume of the solder paste patterns 240A, 240B, 240C, 240D, 240E, 240F, 240G, 240H and 240I may be too large, so that the capacitor 400 may be pushed upwardly from the conductive layer 204-2. The total height Hr of the of the semiconductor package assembly 500C may increase unwantedly and suffer the structural stability of the semiconductor package assembly 500C.

In some embodiments, the solder paste patterns 240 may have various shapes in the top view. For example, in the top views shown in FIGS. 3A to 3I, the solder paste pattern 240 may include a pattern of a hollow square (e.g., the solder paste pattern 240A in FIG. 3A), a square (e.g., the solder paste pattern 240B in FIG. 3B), a square having rounded corners (e.g., the solder paste pattern 240C in FIG. 3C), a hollow circle (e.g., the solder paste pattern 240D in FIG. 3D), a circle (or an oval) (e.g., the solder paste pattern 240E in FIG. 3E), a criss-cross sign (e.g., the solder paste pattern 240F in FIG. 3F), the letter X (e.g., the solder paste pattern 240G in FIG. 3G), an equals sign (e.g., the solder paste pattern 240H in FIG. 3H), or parallel lines (e.g., the solder paste pattern 240I in FIG. 3I) or a combination thereof. In some embodiments, the solder paste patterns 240 may have similar shapes to the solder paste patterns 240A to 240I. In some embodiments, the solder paste patterns 240A, 240B, 240F, 240G, 240H and 240I may have rounded corners.

FIGS. 3A to 3I also show the position of the capacitor 400/the vertical projection 400P of the capacitor 400 (drawn in dashed line) relative to the positions of the solder paste patterns 240 and the conductive layer 204-2. In some embodiments, the solder paste patterns 240A, 240B, 240C, 240D, 240E, 240F, 240G, 240G, 240H and 240I may be in contact with a portion of the back surface 400B (FIG. 2) of the capacitor 400.

In some embodiments, an outer edge of the solder paste pattern 240 may be located within the vertical projection 400P of the capacitor 400 and/or an edge 204-2E of the conductive layer 204-2 in the top view. For example, outer edges 240A-E1, 240B-E, 240C-E, 240D-E1, 240E-E, 240F-E, 240G-E, 240H-E, 240I-E of the solder paste patterns 240A, 240B, 240C, 240D, 240E, 240F, 240G, 240G, 240H and 240I may be located within the vertical projection 400P of the capacitor 400 and/or the edge 204-2E of the conductive layer 204-2, as shown in FIGS. 3A to 3I. In some embodiments as shown in FIG. 3A, a gap G1 enclosed by the capacitor 400, the conductive layer 204-2 and inner edges 240A-E2 of the solder paste pattern 240A may be located in a central portion of the conductive layer 204-2. In some embodiments as shown in FIG. 3D, a gap G2 enclosed by the capacitor 400, the conductive layer 204-2 and inner edge 240D-E2 of the solder paste pattern 240D may be located in a central portion of the conductive layer 204-2. It is noted that the shapes of the solder paste patterns 240A to 240I in the top views shown in FIGS. 3A to 3I may be the shapes of the solder paste patterns according to the original design (e.g., corresponding to the apertures of the solder paste stencil in the solder paste printing process). In the resulting semiconductor package assembly, the shapes of the solder paste patterns 240A to 240I may be changed after performing the fabrication processes. For example, the solder paste patterns 240A to 240I may have irregular edges. For example, the gaps G1 and G2 of the solder paste patterns 240A, 240D (FIGS. 3A and 3D) may be decreased or eliminated (e.g., the inner edges 240A-E2, 240D-E2 of the solder paste patterns 240A, 240D may be merged).

Embodiments provide a semiconductor package assembly. The semiconductor package assembly includes a base, a semiconductor package and a capacitor. The semiconductor package is disposed on the top surface of the base by conductive structures. The capacitor, such as a land-side capacitor, is disposed on the semiconductor package and located between the semiconductor package and the base. The base includes a of the build-up layer structure, a first conductive layer covering the top surface of the of the build-up layer structure, and a solder mask layer covering the first conductive layer. The capacitor has a back surface located away from the semiconductor package and the back surface of the capacitor is located between the top surface and the bottom surface of the base. In some embodiments, the first conductive layer and the solder mask layer both have openings aligned each other to accommodate at least a portion of the capacitor. Therefore, the capacitor may partially overlap the base in a direction substantially parallel with the top surface of the base. When the height (in z-direction) of the conductive structures is reduced to be lower than the height of the capacitor, the total height of the semiconductor package assembly may be reduced without constrained by the height of the capacitor. In some embodiments, the base of the semiconductor package further includes a second conductive layer and a solder paste pattern. The second conductive layer is disposed on the top surface of the of the build-up layer structure and in the opening of the first conductive layer. The back surface of the capacitor may be connected to the second conductive layer by the solder paste pattern directly connected therebetween. Therefore, heat generated from the semiconductor package may quickly transmit to the base by the capacitor, the solder paste pattern and the second conductive layer. In some embodiments, the second conductive layer may be electrically connected to the ground plane of the base to increase the heat dissipation efficiency. In some embodiments, the top view area of the solder paste pattern may be between 40% and 60% of the second top view area of the second conductive layer to improve the heat dissipation efficiency and structural stability without increasing the total height of the semiconductor package assembly.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a base having a top surface and a bottom surface;
a semiconductor package disposed on the top surface of the base; and
a capacitor disposed on the semiconductor package and located between the semiconductor package and the base, wherein the capacitor has a back surface located away from the semiconductor package, and wherein the back surface of the capacitor is higher than the bottom surface of the base and lower than the top surface of the base.

2. The semiconductor package assembly as claimed in claim 1, further comprising:
first contact pads and second contact pads disposed on the semiconductor package and close to the base; and
conductive structures disposed on the first contact pads and electrically connected between the semiconductor package and the base, wherein the capacitor is disposed on the second contact pads and surrounded by the conductive structures.

3. The semiconductor package assembly as claimed in claim 2, wherein a first height of the capacitor is greater than a second height of the conductive structures.

4. The semiconductor package assembly as claimed in claim 1, wherein the base comprises:
a build-up layer structure having a top surface close to the semiconductor package; and
a first conductive layer disposed on the top surface of the build-up layer structure,
a first solder mask layer disposed on the first conductive layer, wherein the top surface of the base is a top surface of the first solder mask layer, and wherein the first solder mask layer has a first opening for accommodate at least a portion of the capacitor.

5. The semiconductor package assembly as claimed in claim 4, wherein the first conductive layer has a second opening aligned to the first opening, and wherein the at least a portion of the capacitor further extends to the second opening.

6. The semiconductor package assembly as claimed in claim 5, wherein the first opening and the second opening surround side surfaces of the capacitor, and wherein the side surfaces are connected to the back surface of the capacitor.

7. The semiconductor package assembly as claimed in claim 5, wherein the back surface of the capacitor is higher than the top surface of the build-up layer structure and lower than the top surface of the first solder mask layer.

8. The semiconductor package assembly as claimed in claim 4, wherein the back surface of the capacitor is higher than a top surface of the first conductive layer and lower than the top surface of the first solder mask layer.

9. The semiconductor package assembly as claimed in claim 5, wherein the base comprises:
a second conductive layer disposed on the top surface of the build-up layer structure and in the second opening of the first conductive layer; and
a solder paste pattern disposed on the second conductive layer and in contact with the capacitor and the second conductive layer.

10. The semiconductor package assembly as claimed in claim 9, wherein the second conductive layer is separate from the first conductive layer.

11. The semiconductor package assembly as claimed in claim 9, wherein the second conductive layer is electrically connected to a ground plane of the base.

12. The semiconductor package assembly as claimed in claim 9, wherein an area occupied by the solder paste pattern is between 40% and 60% of an area of the second conductive layer.

13. The semiconductor package assembly as claimed in claim 9, wherein the solder paste pattern comprises a pattern of a hollow square, a hollow circle, a square, a rectangle, a circle, a criss-cross sign, the letter X, an equals sign, parallel lines, or a combination thereof.

14. The semiconductor package assembly as claimed in claim 9, wherein a first thickness of the first solder mask layer is greater than a second thickness of the solder paste pattern.

15. The semiconductor package assembly as claimed in claim 9, wherein the thickness of the second conductive layer is less than the thickness of the first conductive layer.

16. A semiconductor package assembly, comprising:
a base having a top surface;
a semiconductor package disposed on the top surface of the base by conductive structures, wherein the conductive structures are connected between the top surface of the base and the semiconductor package; and
a capacitor disposed on the semiconductor package and surrounded by the conductive structures, wherein the capacitor partially overlaps the base in a direction substantially parallel with the top surface of the base.

17. The semiconductor package assembly as claimed in claim 16, wherein the base comprises:
a build-up layer structure having a top surface close to the semiconductor package;
a first conductive layer disposed on the top surface of the build-up layer structure; and
a first solder mask layer disposed on the first conductive layer, wherein the first solder mask layer has a first opening for accommodate at least a portion of the capacitor, and wherein the capacitor partially overlaps the first solder mask layer of the base in the direction substantially parallel with the top surface of the base.

18. The semiconductor package assembly as claimed in claim 17, wherein the first conductive layer has a second opening aligned to the first opening, wherein the capacitor partially overlaps the first solder mask layer and the first conductive layer of the base in the direction.

19. The semiconductor package assembly as claimed in claim 18, wherein the base comprises:
a second conductive layer disposed on the top surface of the build-up layer structure and in the second opening of the first conductive layer; and
a solder paste pattern disposed on a portion the second conductive layer and in contact with the capacitor and the second conductive layer.

20. The semiconductor package assembly as claimed in claim 19, wherein an area occupied by the solder paste pattern is between 40% and 60% of an area of the second conductive layer.
